(19) United States
(12) Patent Application Publication
(10) Pub. No.: US 2007/0076276 A1
(43) Pub. Date: Apr. 5, 2007

(54) Color optimization of displayed image for PC projectors

(75) Inventors: Subramanian Jayaram, Austin, TX (US); Lawrence E. Knepper, Austin, TX (US)

Correspondence Address: HAYNES AND BOONE, LLP, 901 MAIN STREET, SUITE 3100, DALLAS, TX, 75202, US

(73) Assignee: Dell Products L.P., Round Rock, TX (US)

(21) Appl. No.: 11/243,804

(22) Filed: Oct. 5, 2005

(51) Int. Cl. G03F 3/08

(52) U.S. Cl. 358/518

(57) ABSTRACT

An image processing engine receives an image data input and provides an image data output, which is displayable on a screen as the projected colored image. A camera is positioned to capture the projected colored image as a feedback data input. The feedback data input is provided by the camera to the image processing engine to control the image data output. A color error block computes a difference between a predefined value of the image data output and the feedback data input. A color compensation block adds the difference to the image data input to generate a compensated image data output, which appears to be projected on the screen that is white in color even though the screen is non-white in color. The image data input is provided by an information handling system (IHS).

### BACKGROUND

The present disclosure relates generally to information handling systems, and more particularly to projection display systems for displaying color images.

As the value and use of information continues to increase, individuals and businesses seek additional ways to acquire, process and store information. One option available to users is information handling systems. An information handling system (‘IHS’) generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Presently, a variety of display systems may be deployed to display information provided by the IHS and/or by multimedia entertainment devices such as optical media players/recorders, television sets, cable and/or satellite receivers, and similar others. For example, some IHS systems may use a liquid crystal display (LCD) and/or plasma display panel. The relative size and cost of the display panel may limit the presentation capability of this display system to a smaller room/audience. A larger size may also limit the portability of the display panel based IHS. Use of projection display systems, including portable projectors, for projecting bigger than life images has become an everyday occurrence, such as in larger presentation rooms and/or in cinema theaters.

Typical examples of commercially available portable projectors include the Dell 3100MP Microportable Projector manufactured by Dell Computers, Round Rock, Tex. and the NEC VT770 portable projector manufactured by NEC Solutions (America), Itasca, Ill. These projector systems may be used in business as well as consumer applications. External factors such as controllable ambient lighting within the presentation room, presence of fluorescent lights, and use of white screens may affect quality of the projected display. The quality of the projected display may be defined in terms of display attributes such as resolution, brightness, luminance, color, and contrast ratio.

Color display images generated by traditional projection systems are often projected on non-white screens such as non-white walls or a portion thereof used as a projection surface. The non-white screen surfaces used as a projection surface may result in incorrect colors being perceived by the viewer. The viewer may manually adjust the color controls for the projection system to compensate for the non-white screen. Some traditional projection systems such as the NEC VT770 projector provide preset controls, by which the viewer may manually select one set of color controls to best suit the screen characteristics. However, most manual adjustments may include a subjective bias and hence may be inconsistent and inefficient. Presently, no tools and/or techniques exist to automatically correct or compensate color display images projected on a non-white projection surface. As a result, many viewers may not fully benefit from the performance of projection systems projecting color displays on non-white screens compared to the projection systems projecting color displays on a white screen.

Therefore, a need exists to provide an improved method and system for automatically controlling color of a display projected on a non-white projection surface. Accordingly, it would be desirable to provide an automatic method and system for improved color projection of display images received from an information handling system absent the disadvantages found in the prior methods discussed above.

### SUMMARY

The foregoing need is addressed by the teachings of the present disclosure, which relates to controlling color of an image projected on a screen. According to one embodiment, an image processing engine receives an image data input and provides an image data output, which is displayable on a screen as the projected colored image. A camera is positioned to capture the projected colored image as a feedback data input. The feedback data input is provided by the camera to the image processing engine to control the image data output.

### BRIEF DESCRIPTION OF THE DRAWINGS

FIG. 1 illustrates a block diagram of an information handling system 100 having an improved projection system, according to an embodiment.

FIG. 2 illustrates a block diagram of an improved projection system, according to an embodiment.

FIG. 3 shows detail of a state machine, according to an embodiment.

FIG. 4 is a flow chart illustrating a method for controlling color of an image projected on a screen, according to an embodiment.

### DETAILED DESCRIPTION

Novel features believed characteristic of the present disclosure are set forth in the appended claims. The disclosure itself, however, as well as a preferred mode of use, various objectives and advantages thereof, will best be understood by reference to the following detailed description of an illustrative embodiment when read in conjunction with the accompanying drawings. The functionality of various circuits, devices, boards, cards, modules, blocks, and/ or components described herein may be implemented as hardware (including discrete components, integrated circuits and systems-on-a-chip ‘SOC’), firmware (including application specific integrated circuits and programmable chips) and/or software or a combination thereof, depending on the application requirements.

Color display images generated by traditional projection systems are often projected on non-white screens such as non-white walls or a portion thereof used as a projection surface. The non-white screen surfaces used as a projection surface may result in incorrect colors being perceived by the viewer. The viewer may manually adjust the color controls for the projection system to compensate for the non-white screen. Presently, no tools and/or techniques exist to automatically correct or compensate color display images projected on a non-white projection surface. As a result, many viewers may not fully benefit from the performance of projection systems projecting color displays on non-white screens compared to projecting color displays on a white screen. Thus, a need exists to provide an improved method and system for automatically controlling color of a display projected on a non-white projection surface.

According to one embodiment, in a method and system for controlling color of an image, an image processing engine receives an image data input and provides an image data output, which is displayable on a screen as the projected colored image. A camera is positioned to capture the projected colored image as a feedback data input. The feedback data input is provided by the camera to the image processing engine to control the image data output. A color error block computes a difference between a predefined value of the image data output and the feedback data input. A color compensation block adds the difference to the image data input to generate a compensated image data output, which appears to be projected on the screen that is white in color even though the screen is non-white in color. The image data input is provided by an information handling system (IHS).

For purposes of this disclosure, an IHS may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, the IHS may be a personal computer, including notebook computers, personal digital assistants, cellular phones, gaming consoles, a network storage device, or any other suitable device and may vary in size, shape, performance, functionality, and price. The information handling system may include random access memory (RAM), one or more processing resources such as central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

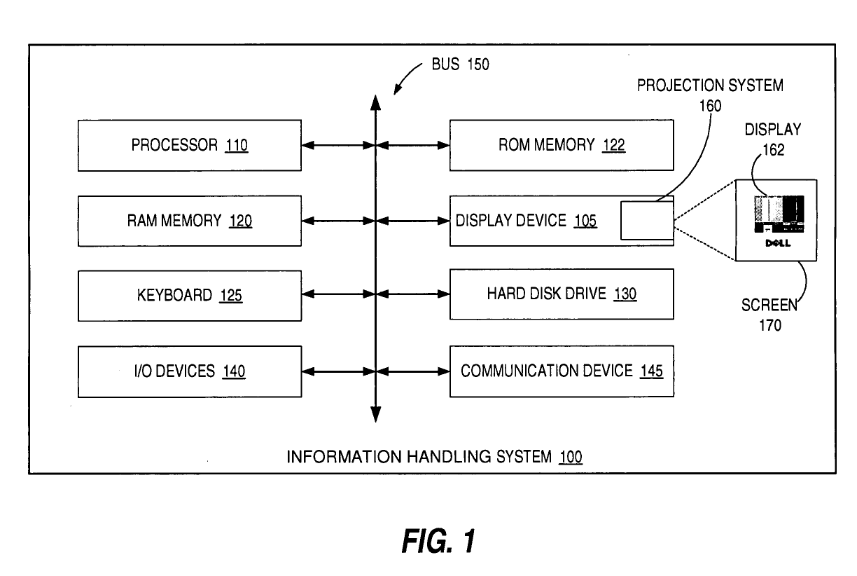

FIG. 1 illustrates a block diagram of an information handling system 100 having an improved display device, according to an embodiment. The information handling system 100 having the improved display device includes a processor 110, a system random access memory (RAM) 120 (also referred to as main memory), a non-volatile ROM 122 memory, a display device 105, a keyboard 125 and an I/O controller 140 for controlling various other input/output devices. For example, the I/O controller 140 may include a keyboard controller, a memory storage drive controller and/or the serial I/O controller. It should be understood that the term “information handling system” is intended to encompass any device having a processor that executes instructions from a memory medium.

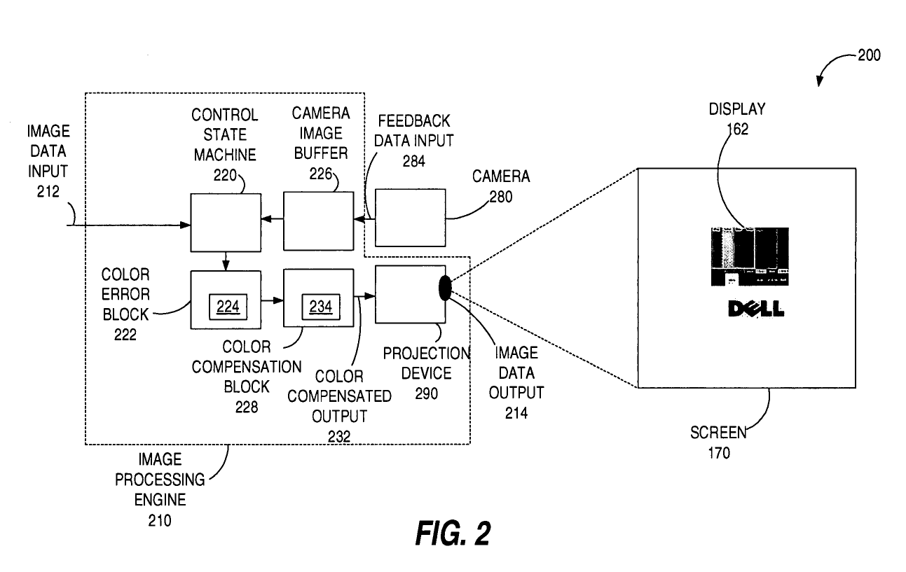

The IHS 100 is shown to include a hard disk drive 130 connected to the processor 110 although some embodiments may not include the hard disk drive 130. The processor 110 communicates with the system components via a bus 150, which includes data, address and control lines. In one embodiment, the IHS 100 may include multiple instances of the bus 150. A communications device 145, such as a network interface card and/or a radio device, may be connected to the bus 150 to enable wired and/or wireless information exchange between the IHS 100 and other devices (not shown). In an exemplary, non-depicted embodiment, the display device 105 includes an improved projection system 160 operable to project at least one display 162 on a screen 170. Additional detail of the improved projection system 160 is described with reference to FIG. 2.

The processor 110 is operable to execute the computing instructions and/or operations of the IHS 100. The memory medium, e.g., RAM 120, preferably stores instructions (also known as a “software program”) for implementing various embodiments of a method in accordance with the present disclosure. For example, in a particular software program, the processor 110 may direct the display device 105 to project the display 162 on the screen 170. In various embodiments the instructions and/or software programs may be implemented in various ways, including procedure-based techniques, component-based techniques, and/or object-oriented techniques, among others. Specific examples include assembler, C, XML, C++ objects, Java and Microsoft Foundation Classes (MFC).

FIG. 2 illustrates a block diagram of an improved projection system 200, according to an embodiment. In the depicted embodiment, the projection system 200 includes an image processing engine 210 coupled to a camera 280. The image processing engine 210 receives an image data input 212 and provides an image data output 214. Included in the image processing engine 210 are an image camera buffer 226 for storing captured images received from the camera 280, a control state machine (CSM) 220 for controlling the color, a color error block 222 for storing a color correction factor in color correction registers 224, a color compensation block 228 for storing a compensated color value in an image frame buffer 234, and a projection device 290 for providing the image data output 214 in the form of a color compensated optical signal.

The CSM 220 receives an image data input 212. In a particular embodiment, the image data input 212 is received as an electrical signal. The electrical signal may be provided by a computer and/or by multimedia entertainment devices such as optical media players/recorders, television sets, cable and/or satellite receivers, and similar others. In the depicted embodiment, the image data input 212 is received from the display device 105 described with reference to FIG. 1. In an embodiment, the projection system 200 is substantially the same as the projection system 160 described with reference to FIG. 1.

In the depicted embodiment, the projection device 290 includes an electrical-to-optical converter (not shown) to convert the electrical input signal to an optical signal. The projection device 290 provides the optical signal as the image data output 214. The image data output 214 is displayable or projectable on the screen 170 as a projected image in the form of the display 162. In an embodiment, the image data output 214 may be generated in response to receiving the image data input 212. In one embodiment, the image data output 214 may be generated independent of the image data input 212. For example, the image processing engine 210 may be configured to display images in a plurality of colors such as red (R), green (G), blue (B), and white that are independent of the image data input 212.

In a particular embodiment, a color of the screen 170 may be white. In another embodiment, the color of the screen may be non-white. A viewer viewing the display 162 projected on the screen 170 having a white color may derive a greater viewing benefit compared to the display 162 projected on the screen 170 having a non-white color.

In a particular embodiment, the camera 280 is positioned and/or aligned to capture the display 162 projected on the screen 170. That is, the camera 280 is focused to receive a reflected image of the display 162 as an optical signal. The camera 280 includes an optical-to-electrical converter (not shown) to convert the captured optical signal to an electrical signal representative of the display 162. The electrical signal, which is a feedback data input 284, may be stored in the camera image buffer 226 and/or be provided to the CSM 220 for controlling color. In a particular embodiment, the camera 280 is a charge coupled device (CCD) camera operable to receive images in color.

It is well known that various models may be used to describe color. Well know models to describe color include an RGB model (an additive color system), a cyan, magenta, yellow and black (CMYK) model (a subtractive color system), and a hue, saturation and value (HSV) model. For example, in the RGB model, the white color is achieved by adding the three primary RGB colors together in equal amounts. Even though the descriptions included herein refer to the RGB model, it is contemplated that the systems and methods described are independent of the color model deployed.

The projection system 200, including the image processing engine 210 and the camera 280, may be characterized by various attributes, properties, characteristics, or parameters such as resolution (e.g., 1600 pixels×1200 pixels) and number of bits per pixel. For example, in a 24 bits-per-pixel projection system, each of the three RGB colors may be defined by 8 bits, giving a range of 256 possible values (or 0-255 intensity levels) for each color. For example, the display 162 having only a red color (full intensity) may be described by an optical signal having a RGB value of (255,0,0), a green only color (full intensity) signal by a RGB value of (0,255,0), a blue only color (full intensity) signal by a RGB value of (0,0,255) and a white color (full intensity) signal by a RGB value of (255,255,255). Other methods of representing color such that white is defined as (R=G=B=0xFF) are also contemplated. Thus, optical as well as electrical signals may be represented by a value of RGB colors that may be varied in intensity on a scale of 0-255 per color for a 24 bits-per-pixel projection system.

As described earlier, the camera 280 provides the feedback data input 284 to the CSM 220 for controlling color. In a particular embodiment, the CSM 220 averages (or linearizes) the R, G and B values received from the camera 280. For example, the value of R may be averaged out over m pixels×n pixels, which is the resolution of the camera 280. In another embodiment, the averaging of the R, G and B values may be performed by the camera 280 and the results of the averaging may be communicated to the CSM 220.

In the depicted embodiment, the CSM 220 computes a color error by comparing a known initial value of the image data output 214 and the feedback data input 284 and storing a difference between the two as the color error in the color correction registers 224 of the color error block 222. In a particular embodiment, the initial image data output 214 projected in the form of the display 162 is a white, full intensity color represented by a RGB value of (255,255,255) and the screen 170 is also white in color. In this embodiment, the initial value of image data output 214 is predefined and known. For this configuration, which may be described as a true color projection system, the feedback data input 284 is also represented by a RGB value of (255,255,255). The color error between the image data output 214 and the feedback data input 284 is substantially zero or RGB (0,0,0), assuming substantially all optical signals reflected from the screen 170 are captured by the camera 280 and losses are negligible.

In a particular embodiment, the screen 170 is non-white in color and one or more colors of the display 162 may appear as incorrect to the viewer. Thus, when the screen 170 is non-white the feedback data input 284 may be represented by RGB value that is different than (255,255,255) and hence, the color error is non-zero. For example, the value for the feedback data input 284 may be RGB (235,255,210) and the color error between the predefined initial value of the image data output 214 and the feedback data input 284 is RGB (255-235,255-255,255-210) or (20,0,45). In one embodiment, the color error stored in the color correction registers 224, may vary from (0,0,0) to (255,255,255).

In a particular embodiment, the color compensation block 228 stores the image data input 212 as a 9-bit value in the input frame buffer 234 and adds the contents of the color correction registers 224 of the color error block 222 to the 9-bit value stored in the input frame buffer 234 to generate a color compensated output 232, which is the 9-bit color corrected value of the image data input 212. For example, the color correction registers 224 having a RGB value (20,0,45) is added to the input data input 212 having a RGB value of (255,255,255) to generate a compensated RGB value of (255+20,255,255+45) or (275,255,300) for the color compensated output 232. The compensated RGB value of (275,255,300) substantially provides the same result as the true color projection system, e.g., an uncompensated image data output 214 being projected on the screen 170 having the white color. That is, the image data output 214 having the compensated value appears to be projected on the screen 170 that is white in color even though the screen 170 is non-white in color.

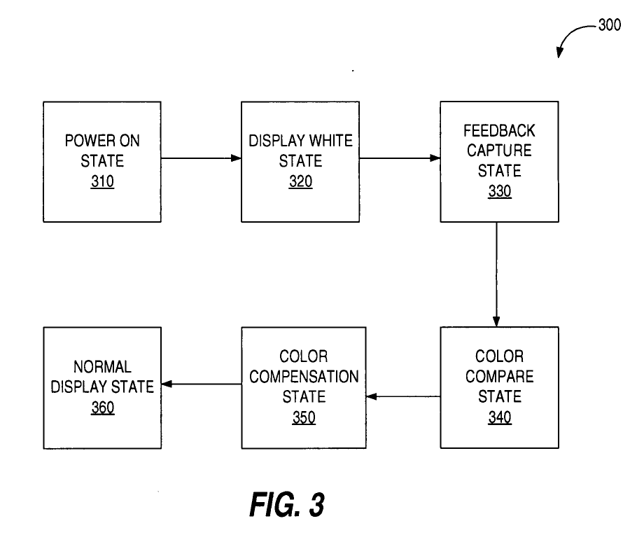

In a normal display state, which is described in additional detail with reference to FIG. 3, the incoming images or pixel data is received as the image data input 212 and the contents of the color correction registers 224 is continuously added to all incoming signal values of the image data input 212 to dynamically and automatically generate the color compensated output 232. Optical signals that are output by the projection device 290 are compensated for a non-white viewing surface of the screen 170 and produce a perceived image having true color on the screen 170 with the non-white viewing surface.

In a particular exemplary, non-depicted embodiment, the color error may be computed as a non-linear function. A non-linear, gamma-like correction factor may be implemented to compensate for projection system applications having a screen color that is a gross departure from white such as a projection surface having a darker or more pronounced hue. In a non-linear implementation of the color error, a color lookup table corresponding to the number of pixels within the camera 280 may be defined to compensate the image data input 212 on a per pixel basis.

FIG. 3 shows detail of a state machine 300, according to an embodiment. In an exemplary, non-depicted embodiment, the state machine 300 is implemented in the image processing engine 210 described with reference to FIG. 2. In the depicted embodiment, the state machine 300 controls a plurality of operating states of the projection system 200 including a power on state 310, a display white state 320, a feedback capture state 330, a color compare state 340, a color compensation state 350, and a normal display state 360. The state machine 300 defines a sequence of transitions among the various operating states, which may be based on occurrence of certain events, conditions, and/or inputs and outputs (not shown). In a particular exemplary, non-depicted embodiment, the transition between the plurality of operating states occurs in a predefined sequence responsive to a clock signal. In an embodiment, the state machine 300 may be implemented in a logic device such as a field programmable gate array (FPGA) and/or an application specific integrated circuit (ASIC).

Upon initial power condition and/or after a reset applied to the projection system 200, the state machine 300 enters the power on state 310 to initialize various components such as buffers and registers and enable the projection system 200 to process inputs and outputs. In the display white state 320, the image data output 214 projected in the form of a predefined display having known initial values, e.g., when the display 162 is a white, full intensity color represented by a RGB value of (255,255,255). In the feedback capture state 330, the camera 280 is positioned to provide the feedback data input 284 to the image processing engine 210 for controlling color. The feedback data input 284 may have a RGB value that may vary between (255,255,255) and (0,0,0). In the color compare state 340, a color error defined as the difference between the predefined value of the image data output 214 and the feedback data input 284 is computed and stored in the color correction registers 224. In the color compensation state 350, the color correction registers 224 of the color error block 222 are added to the image data input 212 to generate the color compensated output 232, which is the image data output 214 having a compensated value. In the normal display state 360, the color correction registers 224 are continuously added in a dynamic and automatic manner to the incoming image data input 212 to update the input frame buffers 234 of the color compensation block 228. The input frame buffers 234 provide the image data output 214 having the compensated value. In a particular exemplary, non-depicted embodiment, the state machine 300 may be reset at any time and/or after a predefined time interval to the power on state 310 to recalibrate the color error.

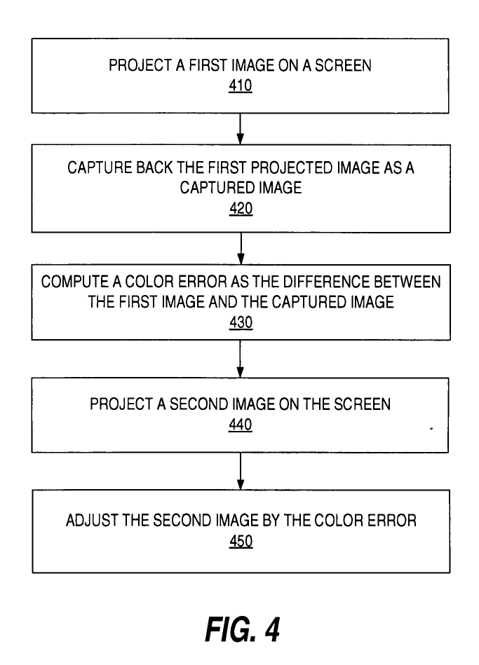

FIG. 4 is a flow chart illustrating a method for controlling color of an image projected on a screen, according to an embodiment. In step 410, a first image is projected on a screen. In an exemplary, non-depicted embodiment, the first image is the display 162 projected on the screen 170. In step 420, the first image projected on the screen is captured back as a captured image. In an exemplary, non-depicted embodiment, the camera 280 captures the display 164 and provides the feedback data input 284 representing the captured image to the image processing engine 210 for controlling color. In step 430, a color error is computed as a difference between the captured image and the first image. In an exemplary, non-depicted embodiment, the color error block 222 computes the color error between the predefined value of the image data output 214 and the feedback data input 284. The first image and the captured image each have a composite RGB value indicative of a color composition of the respective image. The value of the color error, which is computed as a difference between the first composite value and the second composite value, may vary from RGB (0,0,0) to (255,255,255). In step 440, a second image is received for projection on the screen. In step 450, the second image is adjusted by the color error. That is, the color error is added to all newer values of the image data input 212 to dynamically and automatically generate optical signals that are compensated for a non-white viewing surface of the screen 170 and producing a perceived image having true color on the screen 170 with the non-white viewing surface. Thus, an adjustment of the second image by the color error appears to project the second image on the screen that is white in color even though the screen is non-white in color.

Various steps described above may be added, omitted, combined, altered, or performed in different orders. For example an additional step (not shown) may be performed after step 420 to average out the RGB values of the captured image before providing the feedback data input 284.

Although illustrative embodiments have been shown and described, a wide range of modification, change and substitution is contemplated in the foregoing disclosure and in some instances, some features of the embodiments may be employed without a corresponding use of other features. Accordingly, it is appropriate that the appended claims be construed broadly and in a manner consistent with the scope of the embodiments disclosed herein.

What is claimed is:

1. A projector system comprising:
an image processing engine to receive an image data input and provide an image data output, wherein the image data output is displayable on a screen as a projected image; and
a camera positioned to capture the projected image as a feedback data input, wherein the camera provides the feedback data input to the image processing engine to control the image data output.

2. The system of claim 1, wherein the image data input is received as an electrical input signal.

3. The system of claim 2, wherein the image processing engine converts the electrical input signal to an optical signal to form the image data output.

4. The system of claim 1, wherein the image processing engine includes a color error block to compare a predefined value of the image data output and the feedback data input.

5. The system of claim 1, wherein the image processing engine includes a color compensation block to adjust the image data input by a difference between a predefined value of the image data output and the feedback data input.

6. The system of claim 5, wherein the color compensation block adds the difference to the image data input and generates the image data output having a compensated value.

7. The system of claim 6, wherein the difference is substantially equal to zero when the screen is white in color, wherein the difference has a non-zero value when the screen is non-white in color, wherein the image data output having the compensated value appears to be projected on the screen that is white in color even though the screen is non-white in color.

8. The system of claim 1, wherein the image processing engine is operable in a plurality of operating states, wherein the plurality of operating states include a power on state, a display white state, a feedback capture state, a color compare state, a color compensation state, and normal display state.

9. The system of claim 8, wherein the image processing engine operates in each one of the plurality of operating states in a predefined sequence responsive to a clock signal.

10. The system of claim 8, wherein the feedback data input is received during the feedback capture state.

11. The system of claim 1, wherein the image processing engine stores the feedback data input as a composite value for a red, green, and blue color signals.

12. The system of claim 1, wherein the image data input is provided by an information handling system (IHS).

13. A method for controlling color of an image projected on a screen, the method comprising:
projecting a first image on the screen;
capturing the first image projected on the screen as a captured image;
computing a color error as a difference between the captured image and the first image;
receiving a second image for projection on the screen; and
adjusting the second image by the color error.

14. The method of claim 13, wherein the first image has a first composite value indicative of a color composition of the first image.

15. The method of claim 14, wherein the captured image has a second composite value indicative of a color composition of the captured image, wherein the color error is computed as a difference between the first composite value and the second composite value.

16. The method of claim 13, wherein the adjusting of the second image by the color error appears to project the second image on the screen that is white in color even though the screen is non-white in color.

17. The method of claim 13, wherein the first image and the second image is provided by an information handling system (IHS).

18. An information handling system (IHS) comprising:
a processor; and
a display device coupled to the processor, wherein the display device includes:
an image processing engine to receive an image data input from the processor and provide an image data output, wherein the image data output is displayable on a screen as a projected image; and
a camera positioned to capture the projected image as a feedback data input, wherein the camera provides the feedback data input to the image processing engine to control the image data output.

19. The system of claim 18, wherein the image processing engine includes a color error block to compare a predefined value of the image data output and the feedback data input.

20. The system of claim 19, wherein the image processing engine includes a color compensation block to adjust the image data input by a difference between the predefined value and the feedback data input.
